(19) United States
(12) Patent Application Publication
(10) Pub. No.: US 2008/0179645 A1
(43) Pub. Date: Jul. 31, 2008

(54) SEMICONDUCTOR DEVICE AND METHOD OF PRODUCING THE SAME

(75) Inventors: Ko Nakamura, Kawasaki (JP); Takashi Hasegawa, Kawasaki (JP); Yoshihiro Sugiyama, Kawasaki (JP); Hideki Ito, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/016,437

(22) Filed: Jan. 18, 2008

(30) Foreign Application Priority Data
Jan. 29, 2007 (JP) 2007-017972

(51) Int. Cl. H01L 27/00; H01L 21/00

(52) U.S. Cl. 257/295; 438/3; 257/E27.001; 257/E21.001

(57) ABSTRACT

A semiconductor device has a conductive film formed over a substrate, an insulating film formed over the conductive film, and having a hole on the conductive film, and a conductive plug formed in the hole including a barrier metal film and a conductive film. A nitride concentration of the barrier metal film is decreased towards an interface between the barrier metal film and the conductive film, and the nitride concentration of the side of the barrier metal film is higher than the nitride concentration of the side of the conductive film at the interface.

### BACKGROUND OF THE INVENTION

1. Field of the Invention

The present invention relates to a semiconductor device and a method of producing the same.

2. Description of the Related Art

In semiconductor devices such as LSIs, in order to establish electrical connection between layers, conductive plugs are formed in holes in an interlayer insulating film. For example, in a MOS transistor formed on a semiconductor substrate, conductive plugs are formed on impurity diffusion regions, such as source/drain regions, and gate electrodes. In general, a metal silicide layer is formed on a surface layer of such impurity diffusion regions in order to decrease the contact resistance between the impurity diffusion regions and the conductive plugs.

The above-mentioned conductive plugs are mainly composed of tungsten. However, when tungsten diffuses in an interlayer insulating film disposed on the peripheries of the tungsten plugs, a problem of an increase in the leakage current at the boundary between the tungsten plugs and the interlayer insulating film occurs. In addition, when the tungsten constituting the conductive plugs is in contact with the above-mentioned metal silicide layer, the metal silicide layer reacts with the tungsten. As a result, the contact resistance becomes unstable.

Such a diffusion of tungsten and the reaction between tungsten and the above-mentioned metal silicide layer can be prevented by forming a barrier metal film on the outer periphery of the conductive plugs.

However, the formation of such a barrier metal film causes a problem of an increase in the contact resistance between an underlayer, such as a metal silicide layer, and the conductive plugs. As a result, circuits formed on a semiconductor substrate do not function as they are designed to, resulting in a decrease in the yield of the semiconductor device.

Accordingly, it is necessary that the barrier metal film have a property that the contact resistance with an underlayer such as a metal silicide layer does not increase.

### SUMMARY

According to the present invention, there is provided a semiconductor device having a conductive film formed over a substrate, an insulating film formed over the conductive film, and having a hole on the conductive film, and a conductive plug formed in the hole including a barrier metal film and a conductive film. A nitride concentration of the barrier metal film is decreased towards an interface between the barrier metal film and the conductive film, and the nitride concentration of the side of the barrier metal film is higher than the nitride concentration of the side of the conductive film at the interface.

### BRIEF DESCRIPTION OF THE DRAWINGS

FIGS. 1A and 1B are cross-sectional views (part 1) showing steps of a method of producing a semiconductor device according to an embodiment of the present invention;

FIGS. 2A and 2B are cross-sectional views (part 2) showing steps of the method of producing a semiconductor device according to the embodiment of the present invention;

FIGS. 3A and 3B are cross-sectional views (part 3) showing steps of the method of producing a semiconductor device according to the embodiment of the present invention;

FIGS. 4A and 4B are cross-sectional views (part 4) showing steps of the method of producing a semiconductor device according to the embodiment of the present invention;

FIGS. 5A and 5B are cross-sectional views (part 5) showing steps of the method of producing a semiconductor device according to the embodiment of the present invention;

FIGS. 6A and 6B are cross-sectional views (part 6) showing steps of the method of producing a semiconductor device according to the embodiment of the present invention;

FIGS. 7A and 7B are cross-sectional views (part 7) showing steps of the method of producing a semiconductor device according to the embodiment of the present invention;

FIG. 8 is a cross-sectional view (part 8) showing a step of the method of producing a semiconductor device according to the embodiment of the present invention;

FIG. 9 is a cross-sectional view (part 9) showing a step of the method of producing a semiconductor device according to the embodiment of the present invention;

FIG. 10 is a cross-sectional view (part 10) showing a step of the method of producing a semiconductor device according to the embodiment of the present invention;

FIG. 11 is a cross-sectional view (part 11) showing a step of the method of producing a semiconductor device according to the embodiment of the present invention;

FIG. 12 is a cross-sectional view (part 12) showing a step of the method of producing a semiconductor device according to the embodiment of the present invention;

FIG. 13 is a cross-sectional view (part 13) showing a step of the method of producing a semiconductor device according to the embodiment of the present invention;

FIG. 14 is a cross-sectional view (part 14) showing a step of the method of producing a semiconductor device according to the embodiment of the present invention;

FIG. 15 is a flow chart showing main steps of forming first conductive plugs in the method of producing a semiconductor device according to the embodiment of the present invention;

FIG. 16 is a graph showing results of an examination of the contact resistance between a first source/drain region and a first conductive plug thereon in the case where annealing of a nitride of the refractory metal film was omitted;

FIG. 17 is a graph showing results of an examination of the contact resistance between a first source/drain region and a first conductive plug thereon in the cases where annealing of a nitride of the refractory metal film was omitted and the annealing was performed;

FIG. 18 is a graph showing results of an examination of the contact resistance between a contact pad of a gate electrode and a first conductive plug thereon; and

FIG. 19 is a graph that schematically shows profiles of the nitrogen concentration in the cases where annealing of a nitride of the refractory metal film was performed and the annealing was not performed.

### DESCRIPTION OF THE PREFERRED EMBODIMENTS

An embodiment of the present invention will now be described in detail with reference to the attached drawings.

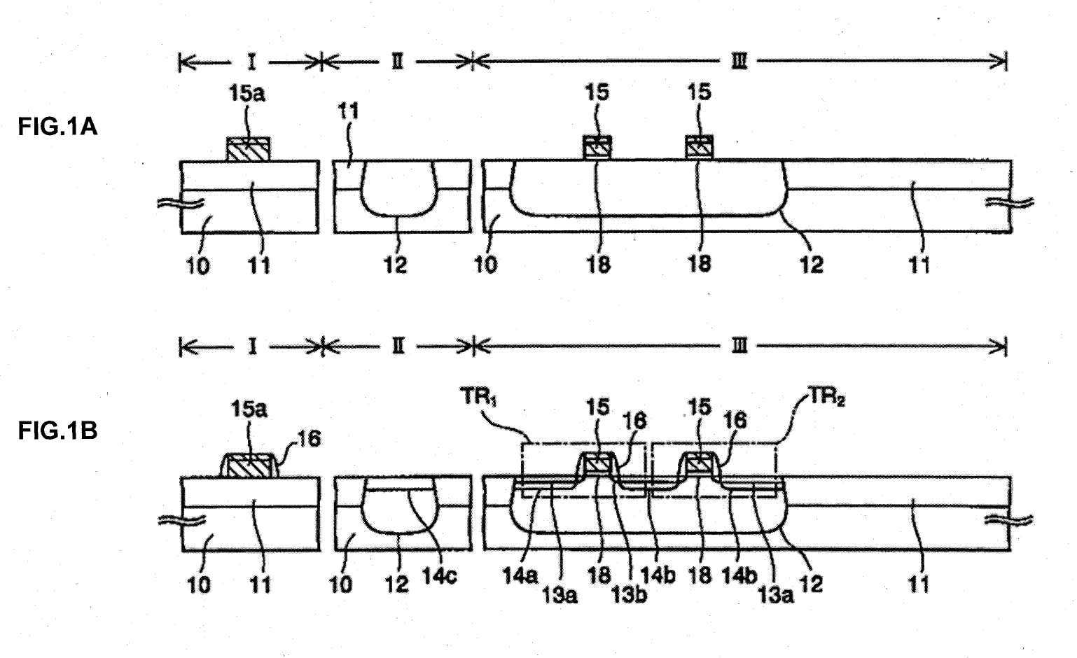

FIGS. 1A to 14 are cross-sectional views showing steps of a method of producing a semiconductor device according to the embodiment of the present invention.

This semiconductor device is a planar ferroelectric random access memory (FeRAM) including a gate contact region I, a well contact region II, and a capacitor-forming region III. This semiconductor device is produced as follows.

The cross-sectional structure shown in FIG. 1A is produced by the steps described below.

First, trenches for shallow trench isolation (STI) are formed on the surface of an n-type or p-type silicon (semiconductor) substrate 10 in order to define an active region of a transistor and the like. An element separation insulating film 11 is formed by embedding an insulating film such as a silicon oxide film in the trenches for STI. The method of forming the element separation insulating film 11 is not limited to STI. Alternatively, the element separation insulating film 11 may be formed by a local oxidation of silicon (LOCOS) method.

P-wells 12 are formed by introducing a p-type impurity in an active region and a well contact region of the silicon substrate 10. Subsequently, a thermal oxidization film, which becomes a gate insulating film 18, is formed by thermally oxidizing the surface of the active region.

A polycrystalline silicon film and a tungsten silicide film are then sequentially formed over the entire top surface of the silicon substrate 10. Gate electrodes (semiconductor patterns) 15 are formed on the capacitor-forming region III by filming the polycrystalline silicon film and the tungsten silicide film by photolithography. A contact pad 15a forming a part of the gate electrodes 15 is formed on the gate contact region I at the same time.

Two gate electrodes 15 are disposed substantially in parallel at an interval on the p-well 12 in the capacitor-forming region III. These gate electrodes 15 form a part of a word line.

Subsequently, as shown in FIG. 1B, an n-type impurity is introduced in areas of the silicon substrate 10, the areas being located at both sides of each of the gate electrodes 15, by ion implantation using the gate electrodes 15 as a mask. Thus, a first source/drain extension 13a and a second source/drain extension 13b are formed.

Subsequently, an insulating film is formed over the entire top surface of the silicon substrate 10. The insulating film is composed of, for example, a silicon oxide film. The silicon oxide film is formed by, for example, a chemical vapor deposition (CVD) method. Insulating side walls 16 are then formed at both sides of each of the gate electrodes 15 and the contact pad 15a by etching back the insulating film.

Furthermore, an n-type impurity is again introduced in the silicon substrate 10 by ion implantation using the insulating side walls 16 and the gate electrodes 15 as a mask. Accordingly, a first source/drain region (impurity diffusion region) 14a and a second source/drain region (impurity diffusion region) 14b are formed on areas of the surface layer of the silicon substrate 10, the areas being located at both sides of each of the gate electrodes 15.

In this ion implantation, the n-type impurity is also introduced in the well contact region II. Accordingly, a well tap region 14c is formed on the surface layer of the silicon substrate 10 in the well contact region II.

A first MOS transistor TR₁ and a second MOS transistor TR₂ that are composed of the gate insulating film 18, the gate electrode 15, the first source/drain region 14a and the second source/drain region 14b are formed in the capacitor-forming region III of the silicon substrate 10 by the above steps.

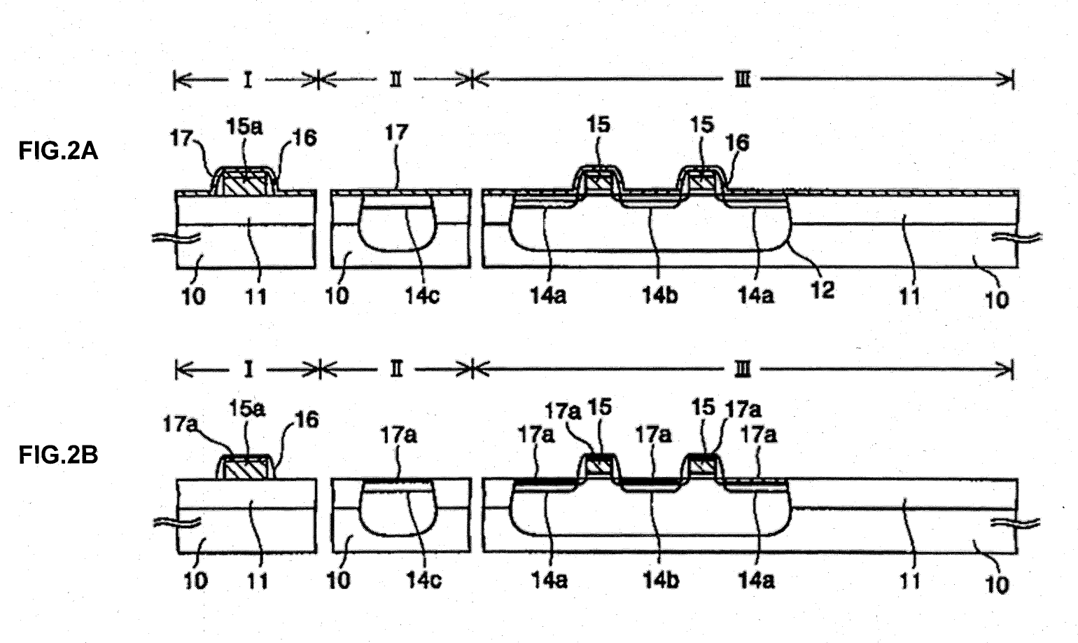

Subsequently, as shown in FIG. 2A, a metal film 17 is formed on the silicon substrate 10, the gate electrodes 15, and the contact pad 15a by a sputtering method. The metal film 17 has a thickness of about 10 nm. The metal film 17 is made of a refractory metal such as cobalt.

Alternatively, the metal film 17 may be made of a titanium film instead of a cobalt film.

The metal film 17 is then annealed in a nitrogen atmosphere. The metal film 17 reacts with silicon in the gate electrodes 15, the contact pad 15a, and the impurity diffusion regions 14a to 14c during this annealing to form a metal silicide film 17a. The metal silicide film 17a is made of cobalt silicide (CoSi).

The annealing is performed under conditions of, for example, at a substrate temperature of 520° C. and an annealing time of 30 seconds.

Subsequently, as shown in FIG. 2B, the unreacted metal film 17 disposed on the element separation insulating film 11 and the insulating side walls 16 is removed by wet etching. The conditions for the wet etching are not particularly limited. Regarding the conditions for the wet etching in this embodiment, an ammonium peroxide mixture (APM) composed of a mixed solution containing NH₄OH, H₂O₂, and H₂O is used as an etchant and the etching time is about five minutes.

Annealing is then performed in a nitrogen atmosphere at a maximum substrate temperature of 840° C. for 30 minutes. Consequently, the cobalt silicide forming the metal silicide film 17a is converted to a low-resistance phase (CoSi₂).

When a titanium film is used as the metal film 17, the maximum temperature of this annealing is 800° C.

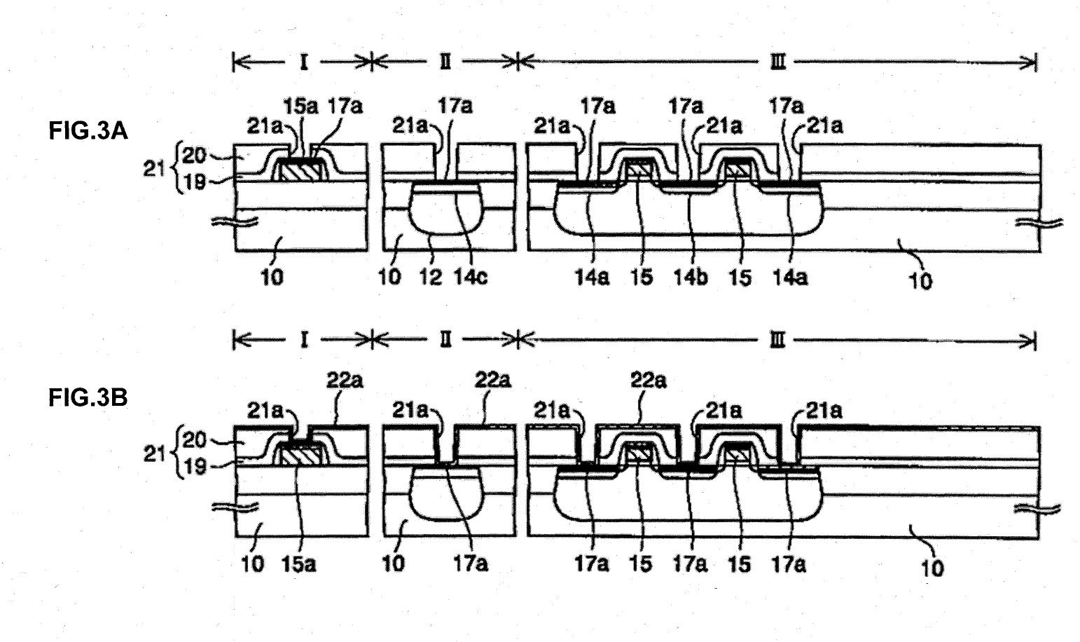

Subsequently, as shown in FIG. 3A, a silicon nitride (SiN) film 19 is formed so as to have a thickness of about 20 nm by a plasma CVD method. A silicon oxide film 20 is then formed on the silicon nitride film 19 so as to have a thickness of about 80 nm by a plasma CVD method using a silane gas. Furthermore, a sacrificial silicon oxide film (not shown) is formed on the silicon oxide film 20 so as to have a thickness of about 1,000 nm by a plasma CVD method using tetraethyl orthosilicate (TEOS) gas. The top surface of the sacrificial silicon oxide film is then planarized by being polished by a chemical mechanical polishing (CMP) method. A first interlayer insulating film 21 is composed of the silicon oxide film 20 that remains after the planarizing and the silicon nitride film 19. As a result of the CMP, the thickness of the first interlayer insulating film 21 is about 700 nm on a flat surface of the silicon substrate 10.

First holes 21a are then formed on the contact pad 15a and the regions 14a to 14c by filming the first interlayer insulating film 21 by photolithography.

Subsequently, as shown in FIG. 3B, a titanium film serving as a barrier metal film 22a is formed on the inner surfaces of the first holes 21a and the top surface of the metal silicide film 17a exposed in the first holes 21a so as to have a thickness of 30 nm by a sputtering method.

The barrier metal film 22a is made of a pure refractory metal. The barrier metal film 22a is preferably made of titanium. The barrier metal film 22a improves the adhesiveness between a conductive film 23 for plugs described below and the metal silicide film 17a. Furthermore, the barrier metal film 22a prevents tungsten forming the conductive film 23 for plugs described below from diffusing in the first interlayer insulating film 21.

The refractory metal forming the barrier metal film 22a may be tantalum instead of titanium.

However, the barrier metal film 22a made of such a pure refractory metal may be oxidized or contaminated after the deposition, resulting in an increase in the contact resistance with the metal silicide film 17a.

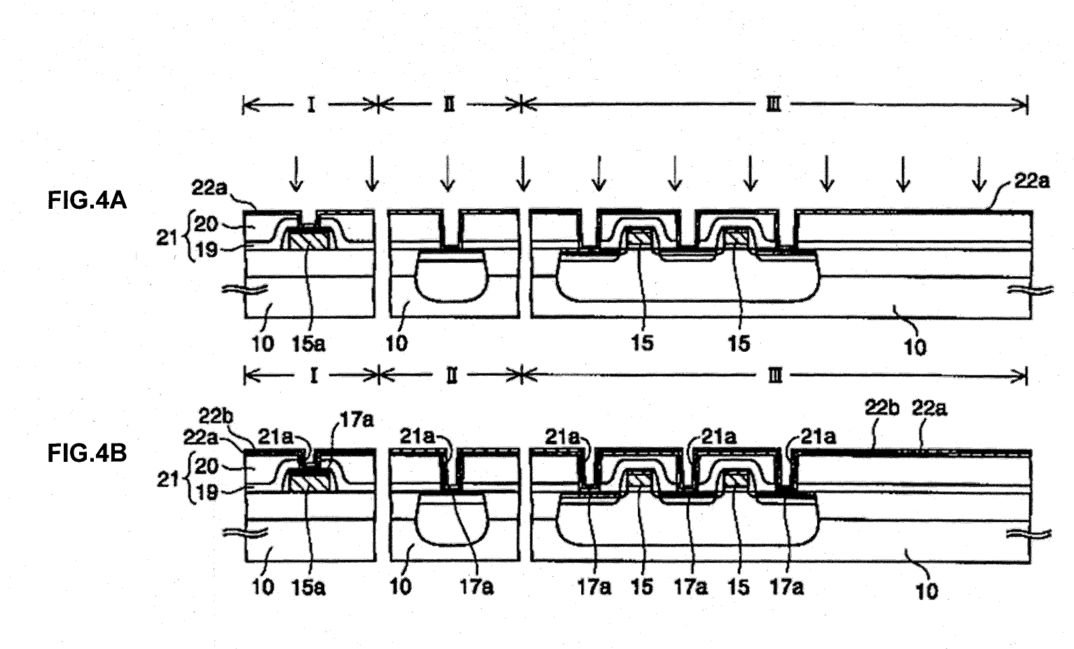

Therefore, in the subsequent step, as shown in FIG. 4A, the barrier metal film 22a is annealed in a 100% nitrogen atmosphere by rapid thermal annealing (RTA). Since the surface of the barrier metal film 22a is nitrided, oxidization and contamination of the surface can be prevented. The annealing is performed, for example, at a maximum substrate temperature of 675° C. and a processing time of 30 seconds.

This RTA need not be performed in a 100% nitrogen atmosphere as long as the atmosphere contains nitrogen. This RTA may be performed in an atmosphere of nitrogen that is diluted with an inert gas such as argon.

However, when the atmosphere contains oxygen, the top surface of the barrier metal film 22a is oxidized. Therefore, the RTA is preferably performed in a nitrogen-containing atmosphere in which oxygen is eliminated.

Subsequently, as shown in FIG. 4B, a nitride of the refractory metal film 22b is formed by a CVD method on the barrier metal film 22a whose surface is nitrided by the annealing. The nitride of the refractory metal film 22b is preferably formed so as to have a thickness of about 20 nm. The nitride of the refractory metal film 22b is preferably a titanium nitride film. A mixed gas containing nitrogen gas, ammonia gas, and TiCl₄ gas is used as a deposition gas in the CVD method. The substrate temperature is preferably 600° C. The nitride of the refractory metal film 22b prevents tungsten forming the conductive film 23 for plugs described below from diffusing in the first interlayer insulating film 21.

The nitride of the refractory metal film 22b may be made of a tantalum nitride film instead of a titanium nitride film.

The nitride of the refractory metal film 22b is made of a nitride of a refractory metal such as titanium nitride or tantalum nitride. Therefore, the nitride of the refractory metal film 22b has an excellent diffusion-preventing ability.

Furthermore, since the nitride of the refractory metal film 22b is formed by a CVD method as in this embodiment, the coverage of the nitride of the refractory metal film 22b is better than that in the case where a sputtering method is employed. Accordingly, even when the aspect ratio of the first holes 21a increases with a miniaturization of the semiconductor device, a nitride of the refractory metal film (i.e., diffusion-preventing film) 22b having a sufficient thickness can be formed on the side faces of the first holes 21a. Therefore, the barrier property on the side faces of the first holes 21a can be satisfactorily ensured.

Since the surface of the barrier metal film 22a is nitrided in advance by annealing in the step shown in FIG. 4A prior to the deposition of the nitride of the refractory metal film 22b, oxidization and contamination of the first barrier metal 22a can be prevented as described above. Therefore, it is not necessary to form the nitride of the refractory metal film 22b immediately after the barrier metal film 22a is formed due to concern over oxidation and contamination of the barrier metal film 22a. Thus, sufficient time can be provided to the production process of the semiconductor device.

Furthermore, the affinity between the barrier metal films 22a made of titanium nitride and the nitride of the refractory metal film 22b can be improved by the annealing. Therefore, stabilization of the contact resistance between the barrier metal films 22a, nitride of the refractory metal film 22b and the metal silicide film 17a can be expected.

However, the present inventor has found that, in some specific types of semiconductor devices, for example, in FeRAMs, even when such annealing is performed, the affinity between the barrier metal film 22a and nitride of the refractory metal film 22b is insufficient and the contact resistance is not stabilized.

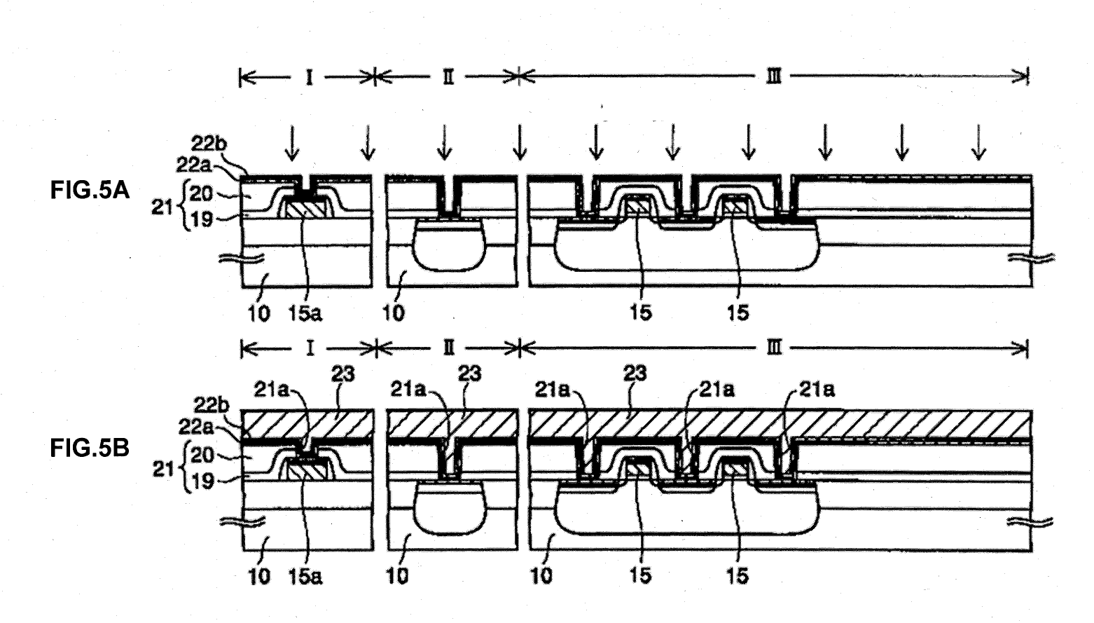

Consequently, in this embodiment, as shown in FIG. 5A, RTA is performed for the nitride of the refractory metal film 22b in a 100% nitrogen atmosphere. By performing the RTA, nitrogen is supplied to the interface between the barrier metal film 22a and the nitride of the refractory metal film 22b through the nitride of the refractory metal film 22b, and thus nitriding of the barrier metal film 22a in the interface can be accelerated.

Accordingly, the affinity and the adhesiveness between the barrier metal film 22a and the nitride of the refractory metal film 22b are satisfactorily improved. Therefore, an increase in the resistance between these films 22a and 22b caused by the difference between the material of the barrier metal film 22a and the material of the barrier metal film 22b can be prevented.

In addition, when the nitride of the refractory metal film 22b is formed by a CVD method, impurities, e.g. chlorine, that are derived from the deposition gas and that are contained in the nitride of the refractory metal film 22b can be released to the outside of the film by the RTA. Accordingly, an increase in the resistance of the nitride of the refractory metal film 22b due to residual impurities can be prevented.

When the maximum substrate temperature in this RTA is equal to or lower than the maximum substrate temperature in the step (FIG. 4A) of annealing the barrier metal film 22a, an effect that is the same as or higher than the effect achieved in the step of annealing the barrier metal film 22a may not be obtained.

Accordingly, the maximum substrate temperature in this step is preferably higher than the maximum substrate temperature in the step (FIG. 4A) of annealing the barrier metal film 22a.

In this embodiment, the annealing (FIG. 4A) of the barrier metal film 22a is performed at a substrate temperature of 675° C. Therefore, the annealing of the nitride of the refractory metal film 22b is preferably performed at a temperature higher than 675° C., for example, at 750° C. or higher.

However, an excessively high substrate temperature causes a phenomenon in which the metal silicide in the metal silicide film 17a is collected in the form of particles by heating. This phenomenon is referred to as “agglomeration” and may cause an increase in the contact resistance of a conductive plug.

In order to prevent agglomeration in the metal silicide film 17a, the upper limit of the maximum substrate temperature in this step is preferably lower than the maximum substrate temperature during the formation of the metal silicide film 17a.

As described above, the process of forming the metal silicide film 17a includes the step (FIG. 2A) of allowing the metal film 17 to react with silicon by annealing and a step (FIG. 2B) of decreasing the resistance of the metal silicide film 17a by annealing. The upper limit of the maximum substrate temperature in this step is preferably set so as to be lower than the maximum substrate temperature in one of the above two steps in which the substrate temperature is higher than that in the other step, that is, the maximum substrate temperature in the step (FIG. 2B) of decreasing the resistance of the metal silicide film 17a.

In this embodiment, the annealing (FIG. 2B) for decreasing the resistance of the metal silicide film 17a is performed at a substrate temperature of 840° C. Therefore, in this step, RTA is performed for the nitride of the refractory metal film 22b at a substrate temperature lower than 840° C. so as to prevent agglomeration in the metal silicide film 17a. This also applies to the above-described annealing (FIG. 4A) for the metal film 22a.

The RTA of the nitride of the refractory metal film 22b is preferably performed at atmospheric pressure. When the RTA is performed at atmospheric pressure, a pump for reducing or increasing the pressure need not be connected to an RTA apparatus, and thus the device structure can be simplified.

Furthermore, the atmosphere of this RTA is not limited to a 100% nitrogen atmosphere as long as oxygen is eliminated. This RTA may be performed in an atmosphere in which nitrogen gas is diluted with an inert gas such as argon gas. By eliminating oxygen from the annealing atmosphere as described above, an increase in the contact resistance between the barrier metal film 22a and each of the nitride of the refractory metal film 22b and the metal silicide film 17a caused by oxidation of the nitride of the refractory metal film 22b can be prevented.

Furthermore, it is expected that the same effect as that in the case where the RTA is performed in a nitrogen atmosphere can be achieved by, for example, a method in which nitrogen contained in the nitride of the refractory metal film 22b is diffused in the barrier metal film 22a. That is, it is expected that even when the RTA is performed in an inert gas atmosphere not containing nitrogen, an increase in the resistance between the barrier metal film 22a and the nitride of the refractory metal film 22b can be prevented.

The processing time of the RTA is not particularly limited as long as the reaction between the barrier metal film 22a and the nitride of the refractory metal film 22b is sufficiently conducted within the time. For example, the processing time of the RTA is 120 seconds or less. In this embodiment, the standby temperature of the RTA apparatus is in the range of 150° C. to 200° C. The temperature is increased to the target substrate temperature within 5 to 7 seconds from the start of heating. The annealing is finished 30 seconds from the start of heating.

Subsequently, as shown in FIG. 5B, a conductive film 23 for plugs made of tungsten is formed by a CVD method. A mixed gas containing WF₆ gas, SiH₄ gas, and hydrogen gas is used as the deposition gas in the CVD method. The substrate temperature in the CVD method is maintained at 410° C. The first holes 21a are completely filled with the conductive film 23 for plugs.

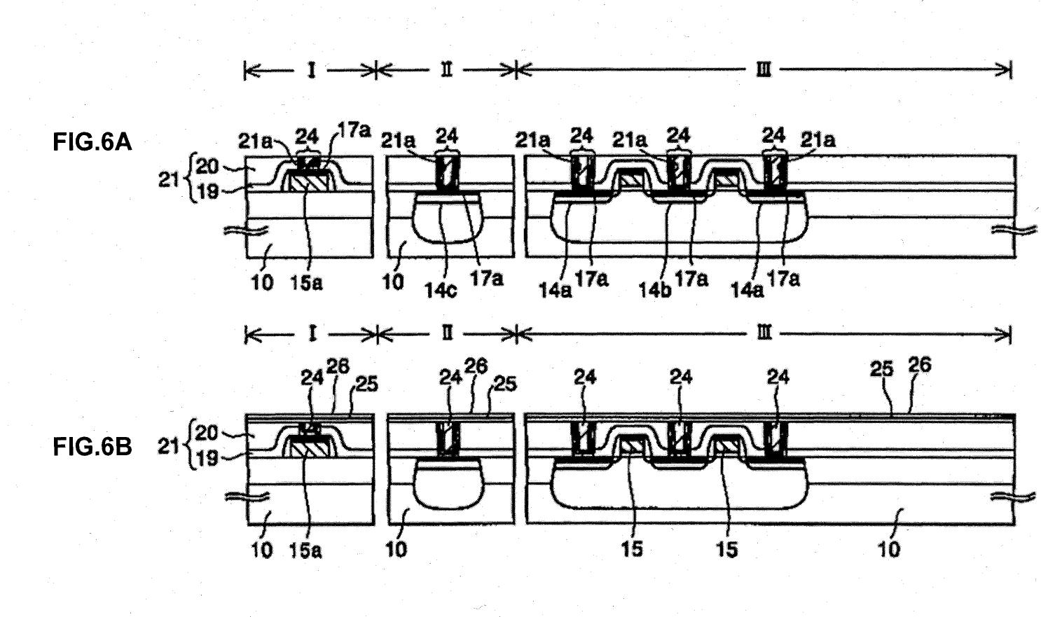

Subsequently, as shown in FIG. 6A, unnecessary portions of the barrier metal film 22a, the nitride of the refractory metal film 22b, and the conductive film 23 for plugs on the first interlayer insulating film 21 are removed by being polished by a chemical mechanical polishing (CMP) method. These films remain as first conductive plugs 24 in the first holes 21a. The above films may be removed by an etch-back method instead of the CMP method.

The first conductive plugs 24 are mainly composed of tungsten. Tungsten is oxidized very easily, and oxidization of tungsten during a process causes contact failures.

Accordingly, in the subsequent step, as shown in FIG. 6B, an anti-oxidation film 25 is formed by a plasma CVD method. The anti-oxidation film 25 is formed in order to protect the first conductive plugs 24 from an oxidizing atmosphere. The anti-oxidation film 25 is preferably a silicon oxynitride (SiON) film. The anti-oxidation film 25 is formed so as to have a thickness of, for example, about 100 nm. An insulating adhesion film 26 is further formed on the anti-oxidation film 25 by a plasma CVD method using TEOS gas. The insulating adhesion film 26 is composed of, for example, a silicon oxide film. The insulating adhesion film 26 is preferably formed so as to have a thickness of about 130 nm.

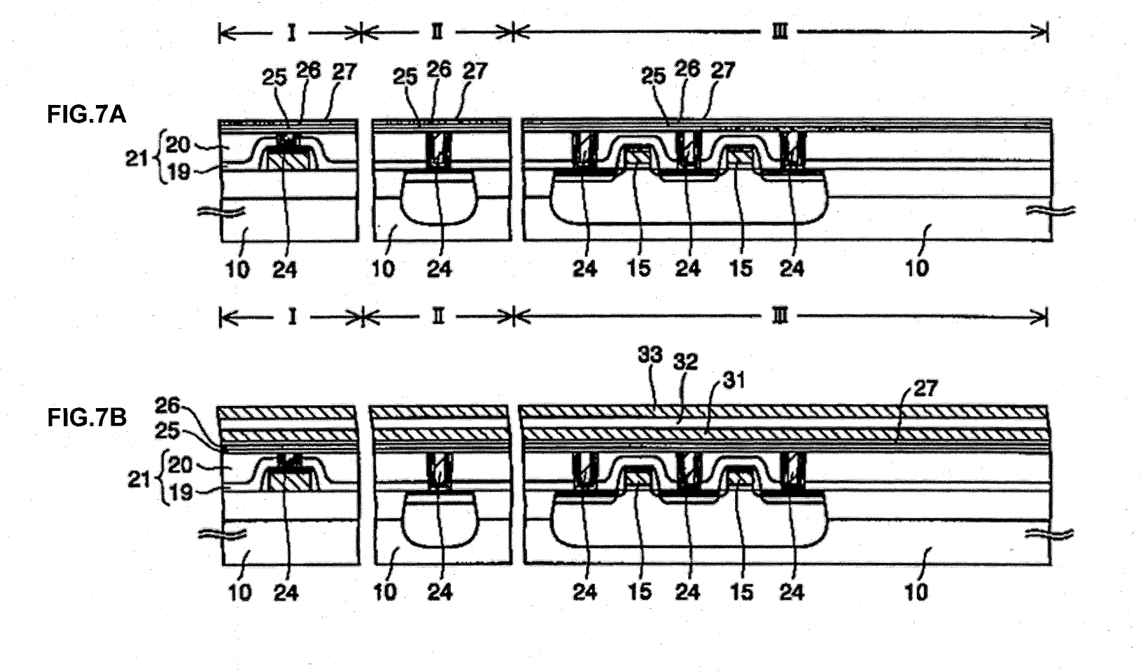

Subsequently, as shown in FIG. 7A, a first alumina film 27 is formed on the insulating adhesion film 26. The first alumina film 27 increases the crystallinity of a lower electrode of a ferroelectric capacitor described below and consequently improves the crystallinity of a capacitor dielectric film. The first alumina film 27 is preferably formed by a sputtering method so as to have a thickness of about 20 nm.

The cross-sectional structure shown in FIG. 7B is produced by the steps described below.

First, a first conductive film 31 composed of a noble metal film, e.g., a platinum film, is formed by a sputtering method. The first conductive film 31 is preferably formed so as to have a thickness of about 150 nm.

A ferroelectric film 32 made of lead zirconate titanate (PZT) is then formed on the first conductive film 31 by a sputtering method. The ferroelectric film 32 is preferably formed so as to have a thickness of about 150 nm. Instead of a sputtering method, a metal organic CVD (MOCVD) method or a sol-gel method may be used as the method of forming the ferroelectric film 32. Furthermore, the material of the ferroelectric film 32 is not limited to PZT mentioned above. Alternatively, the ferroelectric film 32 may be made of a Bi-layered structure compounds such as SrBi₂Ta₂O₉ or SrBi₂ (Ta, Nb)₂O₉, lead-lanthanum-zirconate-titanate (PLZT) in which lanthanum is doped in PZT, or another metal oxide ferroelectric material.

Subsequently, the PZT forming the ferroelectric film 32 is crystallized by performing RTA in an atmosphere containing 2.5% of oxygen and 97.5% of argon. Regarding an example of the conditions for the RTA, the substrate temperature is 563° C., the annealing time is 90 seconds, and the temperature increasing rate is 125° C./sec. Such annealing is also referred to as “calcination”.

Subsequently, an iridium oxide (IrO₂) film forming a lower layer of a second conductive film 33 is formed on the ferroelectric film 32 by a sputtering method so as to have a thickness of about 50 nm. In order to increase the ferroelectricity of the ferroelectric film 32, the lower layer is most preferably made of iridium oxide as in this embodiment. Alternatively, the lower layer may be composed of a noble metal film such as an iridium film or a platinum film as needed.

The PZT forming the ferroelectric film 32 is then crystallized through the lower layer by performing RTA in an atmosphere containing 1% of oxygen and 99% of argon. Regarding an example of the conditions for the RTA, the substrate temperature is 708° C., the annealing time is 20 seconds, and the temperature increasing rate is 125° C./sec. Such annealing is also referred to as “crystallization annealing”.

Subsequently, an iridium oxide film forming an upper layer of the second conductive film 33 is formed on the iridium oxide lower layer so as to have a thickness of about 200 nm. This upper layer is composed of a noble metal film or a noble metal oxide film. Instead of the iridium oxide film, the upper layer may be composed of a noble metal film such as an iridium film or a platinum film.

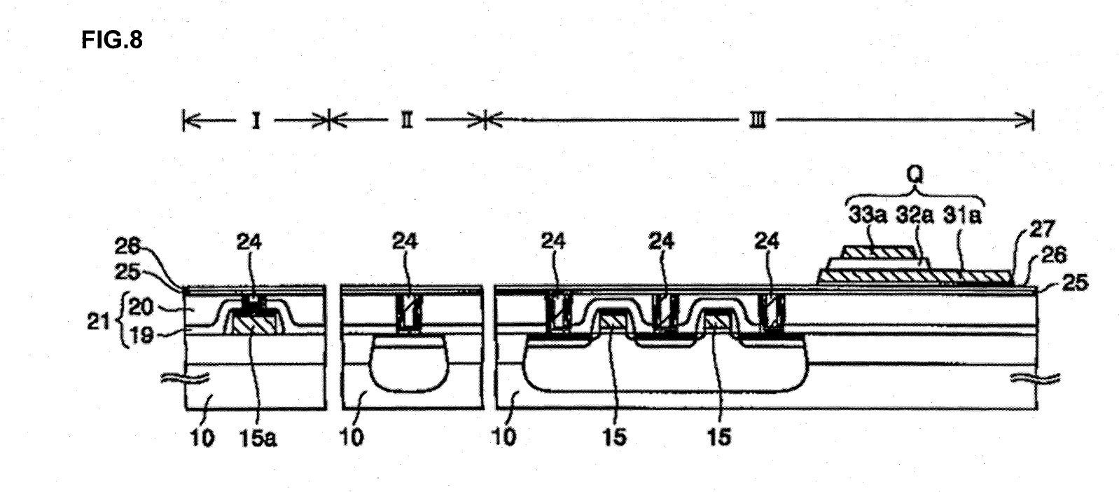

Subsequently, as shown in FIG. 8, the second conductive film 33, the ferroelectric film 32, and the first conductive film 31 are separately patterned by photolithography in that order. The filmed second conductive film 33, ferroelectric film 32, and first conductive film 31 form an upper electrode 33a, a capacitor dielectric film 32a, and a lower electrode 31a, respectively, which constitute a ferroelectric capacitor Q.

A part of the first alumina film 27 that is not covered with the lower electrode 31a is removed by the above filming process.

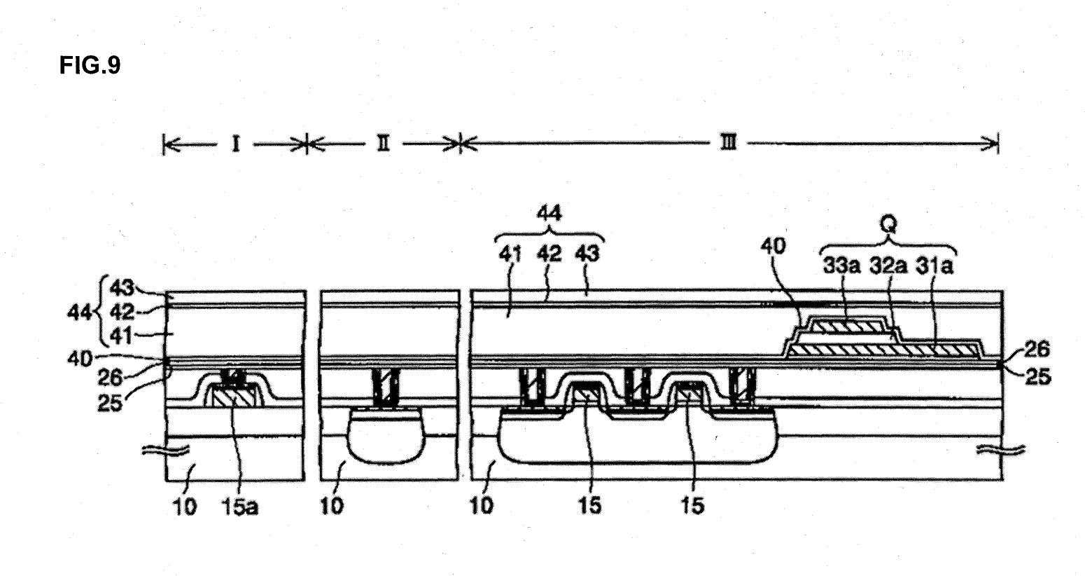

The cross-sectional structure shown in FIG. 9 is produced by the steps described below.

First, a second alumina film 40 for protecting the capacitor Q from a reducing atmosphere such as hydrogen and preventing the degradation of the capacitor dielectric film 32a is formed over the entire top surface of the silicon substrate 10. The second alumina film 40 is formed by a sputtering method so as to have a thickness of about 20 nm.

In order that the capacitor dielectric film 32a recovers from damage caused by the previous processes such as etching and sputtering, annealing is performed in a furnace at a substrate temperature of 650° C. Such annealing is also referred to as “recovery annealing”.

The recovery annealing is preferably performed in an oxygen-containing atmosphere in order to compensate for oxygen deficiency in the capacitor dielectric film 32a. In this embodiment, the recovery annealing is performed in a 100% oxygen atmosphere.

Subsequently, a silicon oxide film 41 is formed on the second alumina film 40 by a plasma CVD method using TEOS gas as a reaction gas so as to have a thickness of about 1,500 nm. Consequently, irregularities reflecting the shape of the capacitor Q are formed on the top surface of the silicon oxide film 41. In order to remove these irregularities, the top surface of the silicon oxide film 41 is planarized by being polished by a CMP method. The thickness of the silicon oxide film 41 is preferably about 1,000 nm on the flat surface of the second alumina film 40.

In order to perform a dehydration treatment of the silicon oxide film 41, the surface of the silicon oxide film 41 is then exposed to a N₂O plasma. Instead of this N₂O plasma treatment, the dehydration treatment of the silicon oxide film 41 may be performed by annealing in a furnace.

Subsequently, a third alumina film 42 for protecting the capacitor Q from hydrogen and moisture to be generated in the subsequent steps is formed on the silicon oxide film 41 by a sputtering method so as to have a thickness of about 50 nm. Furthermore, a silicon oxide film 43 is formed on the third alumina film 42 by a plasma CVD method so as to have a thickness of about 200 nm.

A second interlayer insulating film 44 composed of the silicon oxide films 41 and 43 and the third alumina film 42 is formed on the capacitor Q by the above-described steps.

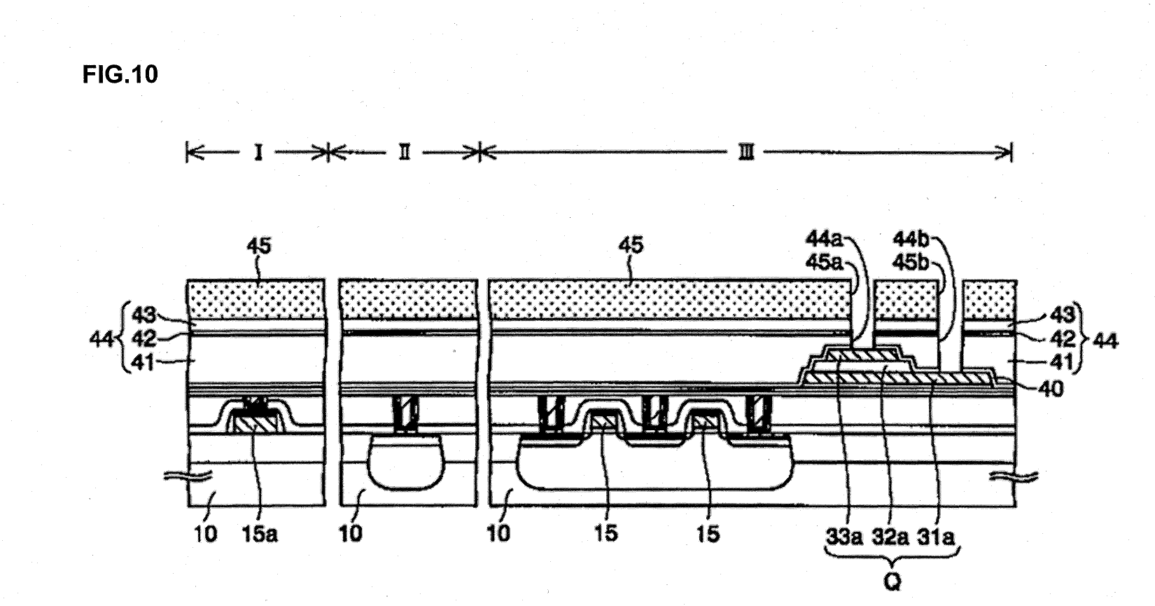

Subsequently, as shown in FIG. 10, a first resist film 45 having a first window 45a and a second window 45b, i.e., holes, is formed on the second interlayer insulating film 44. The first resist film 45 is formed by applying a photoresist on the second interlayer insulating film 44, exposing the resist layer, and then developing the resist layer.

The silicon substrate 10 is then charged in a parallel plate plasma etching chamber. The second interlayer insulating film 44 and the second alumina film 40 provided on the silicon substrate 10 are etched through the first window 45a and the second window 45b. A mixed gas of C₄F₈, Ar, O₂ and CO is used as an etching gas. Consequently, a second hole 44a and a third hole 44b are formed on the upper electrode 33a and the lower electrode 31a, respectively, through the second interlayer insulating film 44.

The first resist film 45 is then removed. Subsequently, in order that the capacitor Q recovers from damage caused by the previous processes, annealing may be performed, for example, in an oxygen atmosphere at a substrate temperature of 500° C. for 60 minutes.

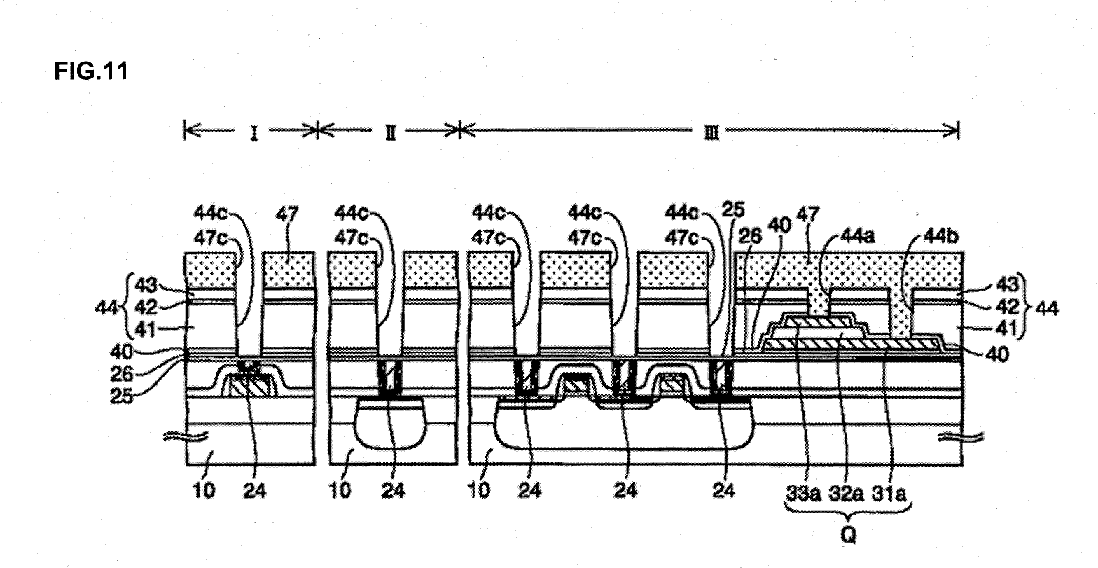

Subsequently, as shown in FIG. 11, a photoresist is again applied on the second interlayer insulating film 44. The photoresist is then exposed and developed to form a second resist film 47 having fourth windows 47c, i.e., holes, on the first conductive plugs 24. The second hole 44a and the third hole 44b are covered with the second resist film 47.

Fourth holes 44c are formed on the first conductive plugs 24 by etching the second interlayer insulating film 44, the second alumina film 40, and the insulating adhesion film 26 through the fourth windows 47c. This etching is performed with a parallel plate plasma etching apparatus using a mixed gas of C₄F₈, Ar, O₂, and CO as an etching gas. In this step, the anti-oxidation film 25 functions as a stopper film in this etching, and the etching is stopped on the anti-oxidation film 25.

The second resist film 47 is then removed.

As described above, the deep fourth holes 44c are formed on the first conductive plugs 24 in the step different from the step of forming the shallow second hole 44a and the third hole 44b on the capacitor Q. Therefore, this method can prevent the capacitor Q from degrading by being exposed to the etching atmosphere for a long time.

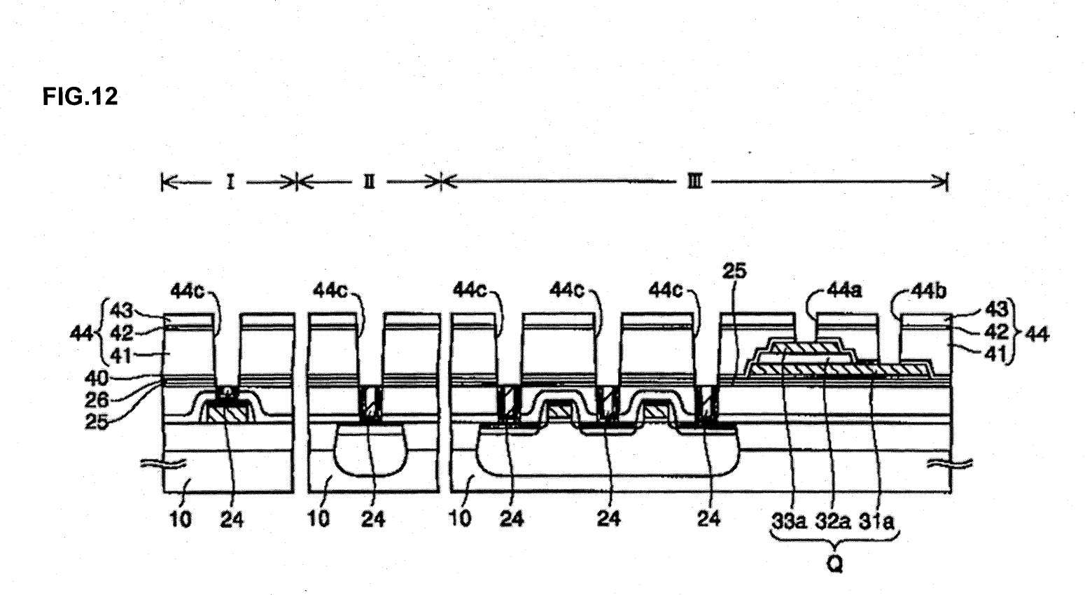

The cross-sectional structure shown in FIG. 12 is produced by the step described below.

First, the silicon substrate 10 is charged in a parallel plate plasma etching chamber. A mixed gas of CHF₃, Ar, and O₂ is supplied to the etching apparatus as an etching gas. Consequently, the anti-oxidation film 25 disposed at the bottom of the fourth holes 44c is removed by being exposed to the etching atmosphere, and the first conductive plugs 24 are exposed on the bottom of the fourth holes 44c. Furthermore, foreign matter in the second hole 44a and the third hole 44b is removed at the same time, thus cleaning the top surfaces of the upper electrode 33a and the lower electrode 31a.

In addition, the first conductive plugs 24 are covered with the anti-oxidation film 25 until this step is finished. Accordingly, the occurrence of contact failure due to oxidation of tungsten constituting the first conductive plugs 24 can be prevented.

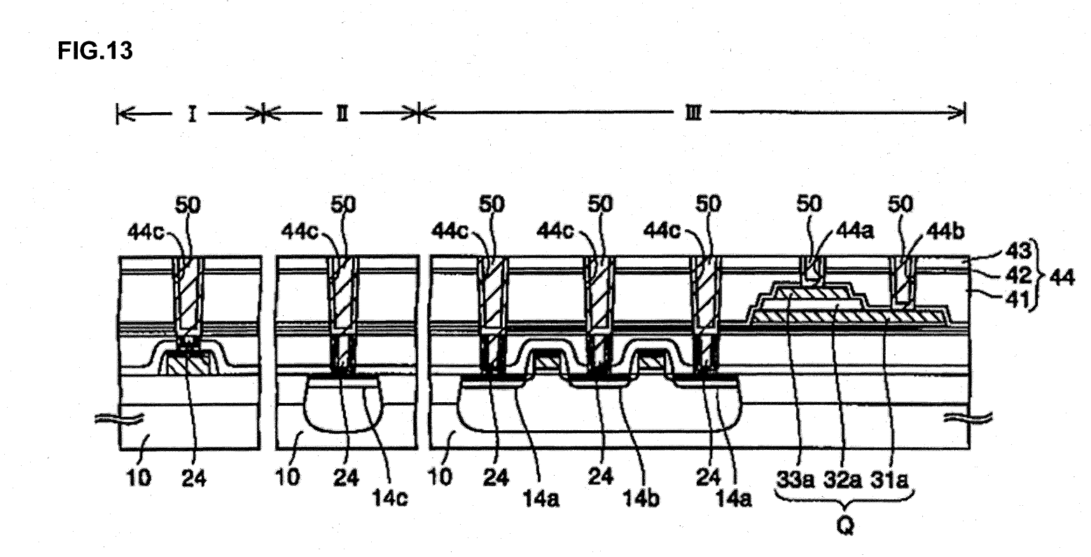

The cross-sectional structure shown in FIG. 13 is produced by the steps described below.

First, in order to clean the inner surfaces of the second hole 44a, the third hole 44b, and the fourth holes 44c, the inner surfaces of the holes 44a to 44c are exposed to an argon plasma atmosphere generated by a high-frequency power. The inner surfaces of the second hole 44a, the third hole 44b, and the fourth holes 44c are subjected to sputter etching. A barrier metal film made of titanium nitride is then formed on the inner surfaces of the second hole 44a, the third hole 44b, and the fourth holes 44c and on the second interlayer insulating film 44 by sputtering so as to have a thickness of about 100 nm.

A tungsten film is then formed on the barrier metal film by a CVD method. The second hole 44a, the third hole 44b, and the fourth holes 44c are completely filled with the tungsten film.

Unnecessary portions of the barrier metal film and the tungsten film disposed on the top surface of the second interlayer insulating film 44 are then removed by being polished by a CMP method. These films remain in each of the holes 44a to 44c as second conductive plugs 50.

Among the second conductive plugs 50, second conductive plugs 50 formed in the second hole 44a and the third hole 44b are electrically connected to the upper electrode 33a and the lower electrode 31a, respectively, and second conductive plugs 50 formed in the fourth holes 44c are electrically connected to the first conductive plugs 24.

The above connecting structure including the first conductive plug 24 and the second conductive plug 50 formed on each of the impurity regions 14a to 14c so as to have a two-stage structure is referred to as “via-to-via structure”.

In the via-to-via structure, the holes 21a and the holes 44c which are filled with the plugs are formed in separate steps. Therefore, the amounts of etching for forming the holes 21a and the holes 44c are smaller than the amounts of etching when these holes 21a and 44c are formed by simultaneous etching. Accordingly, these holes can be easily formed.

Furthermore, when the holes 21a and 44c are formed by simultaneous etching, the aspect ratio of the entire holes is increased, resulting in a difficulty in the formation of the conductive plugs. In contrast, in the via-to-via structure, the first conductive plugs 24 and the second conductive plugs 50 can be easily formed in the holes 21a and the holes 44c, respectively.

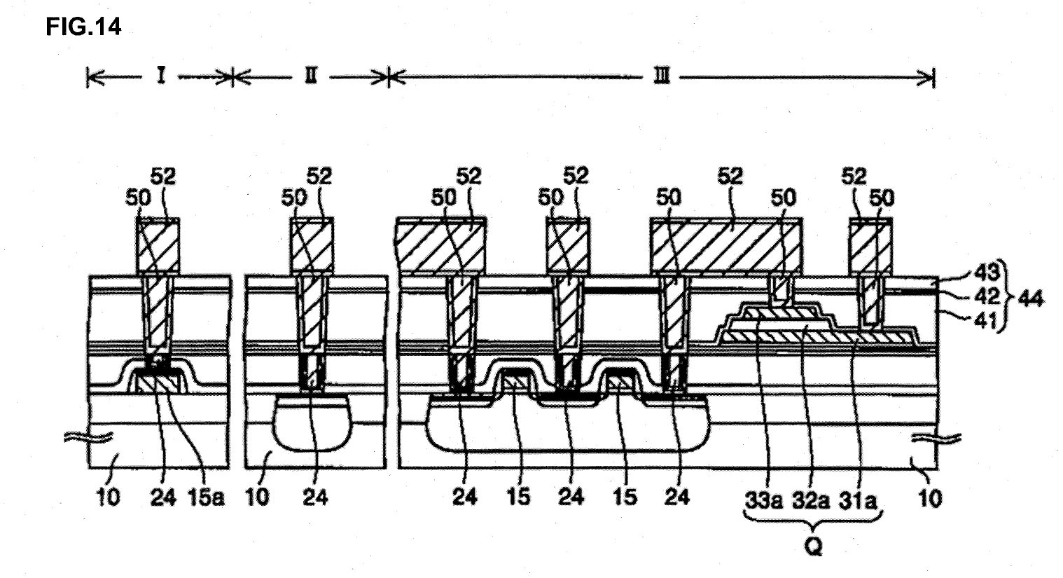

The cross-sectional structure shown in FIG. 14 is produced by the steps described below.

First, a titanium film and a titanium nitride film are sequentially formed by a sputtering method on the second interlayer insulating film 44 and the second conductive plugs 50. The thickness of the titanium film is about 60 nm, and the thickness of the titanium nitride film is about 30 nm. These titanium film and titanium nitride film function as a barrier metal film. Subsequently, a copper-containing aluminum film, a titanium film, and a titanium nitride film are sequentially formed as a metal laminated film on the barrier metal film by a sputtering method. The thickness of the copper-containing aluminum film is about 360 nm, the thickness of the titanium film is about 5 nm, and the thickness of the titanium nitride film is about 70 nm.

Subsequently, a silicon oxynitride film (not shown) is formed as an antireflection film on the metal laminated film. A first metal wiring layer 52 is then formed by filming the metal laminated film and the barrier metal film by photolithography. A copper film may also be used as the first metal wiring layer 52 instead of the above-mentioned metal laminated film containing an aluminum film.

A third interlayer insulating film and a second metal wiring layer are then sequentially formed on the first metal wiring layer 52. However, a detailed description of the steps of forming these films is omitted.

Thus, a fundamental structure of the semiconductor device according to this embodiment is produced.

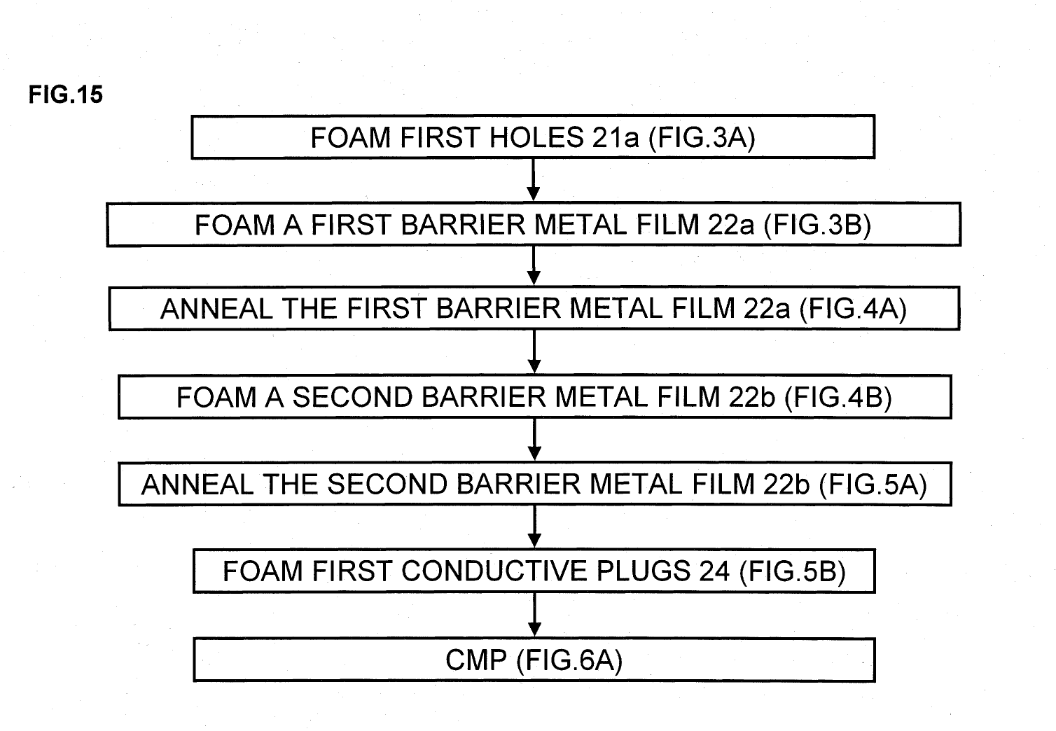

FIG. 15 is a flow chart showing main steps of forming the first conductive plugs 24 in the method of producing the above semiconductor device.

As shown in FIG. 15, in this embodiment, annealing is performed for the nitride of the refractory metal film 22b made of titanium nitride in a nitrogen atmosphere in the step shown in FIG. 5A. Consequently, nitrogen is supplied to the interface between the barrier metal film 22a and the nitride of the refractory metal film 22b to improve the affinity and the adhesiveness between the barrier metal film 22a and the nitride of the refractory metal film 22b. Furthermore, the contact resistance between the first conductive plug 24, which includes the barrier metal film 22a and the nitride of the refractory metal film 22b, and the metal silicide film 17a can be stabilized.

Such a stabilization of the contact resistance can be realized in each region of the first source/drain region 14a, the second source/drain region 14b, the well tap region 14c, and the contact pad 15a regardless of the positions where the metal silicide film 17a is provided.

The present inventor conducted an examination described below in order to confirm the stabilization of the contact resistance.

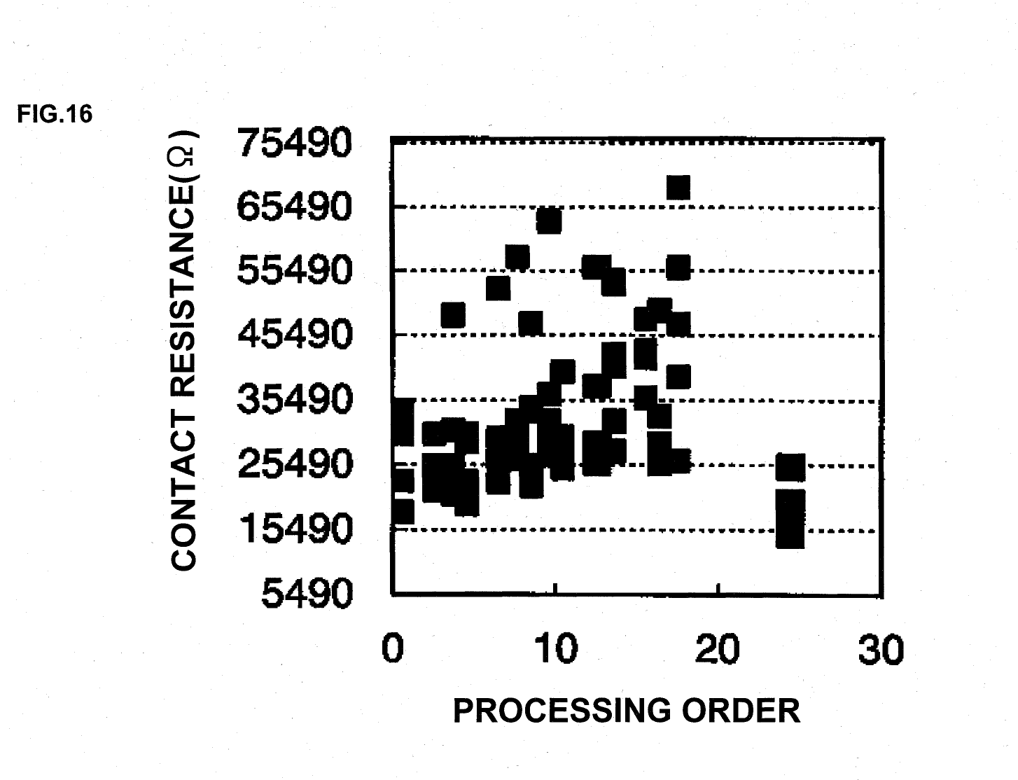

FIG. 16 is a graph showing results of an examination of the contact resistance between a first source/drain region 14a and a first conductive plug 24 thereon in the case where the annealing of the nitride of the refractory metal film 22b described in FIG. 5A was omitted.

This examination was conducted using one lot (including 25 substrates) of silicon substrates 10. The horizontal axis of FIG. 16 represents the processing order which represents an order in which silicon substrates 10 are processed in the lot.

The contact resistances were measured in the via-to-via structure described in FIG. 13. This also applied to other examinations described below.

As shown in FIG. 16, when the annealing of the nitride of the refractory metal film 22b was omitted, the contact resistances varied in the lot. In particular, in ascending processing order of the silicon substrates 10, the contact resistance tended to increase.

Furthermore, the contact resistances of the substrates in the lot used in this examination varied as shown in the graph, whereas those in another lot did not vary. Thus, when the annealing of the nitride of the refractory metal film 22b was omitted, the behavior of the contact resistances of the first conductive plugs 24 became extremely unstable.

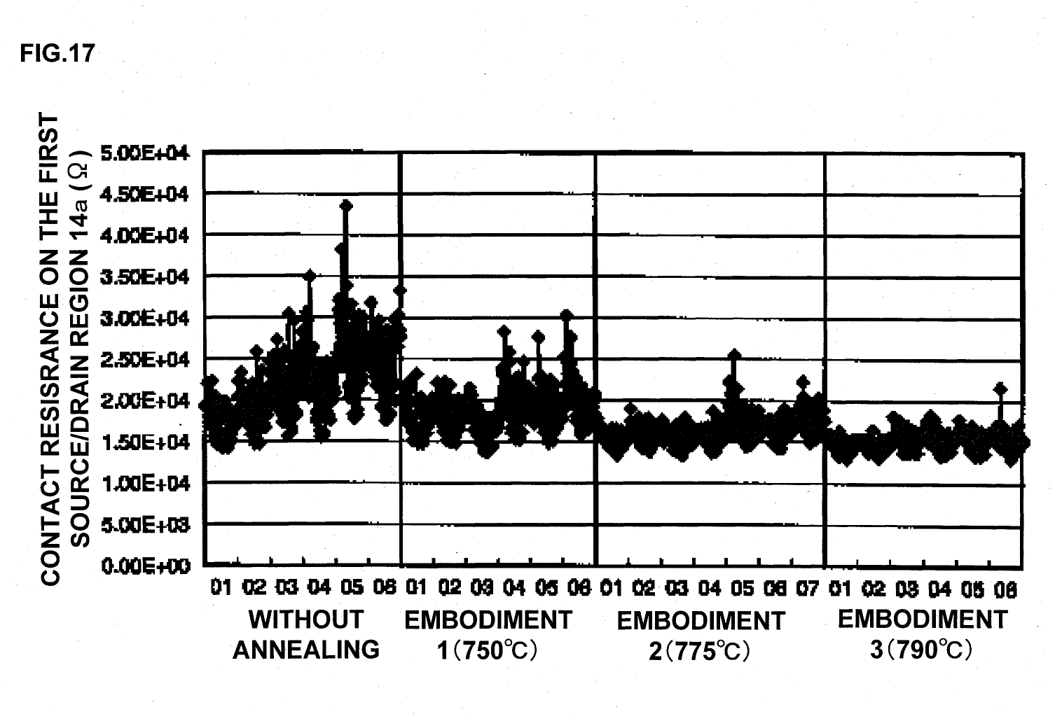

FIG. 17 is a graph showing results of an examination of the contact resistance between a first source/drain region 14a and a first conductive plug 24 thereon in the cases where the annealing of the nitride of the refractory metal film 22b was omitted and the annealing was performed as in the above embodiment.

The horizontal axis of FIG. 17 represents the processing order which represents an order in which silicon substrates 10 are processed.

In order to examine the effect of the maximum substrate temperature during annealing of the nitride of the refractory metal film 22b on the contact resistance, the maximum substrate temperature was varied in the experiments of this examination. Embodiment 1, Embodiment 2, and Embodiment 3 shown in the horizontal axis of FIG. 17 show experimental results obtained when the annealing was performed at a maximum substrate temperature of 750° C., 775° C., and 790° C., respectively.

As shown in FIG. 17, when the annealing was omitted, the contact resistances markedly varied as in the case shown in FIG. 16.

In contrast, the contact resistances in Embodiments 1 to 3, in which the annealing was performed, were substantially the same value regardless of the number of order of processed silicon substrates 10. These results showed that variations in the contract resistance in the lot could be reduced by the annealing.

In particular, in Embodiment 3 in which the maximum substrate temperature during the annealing was 790° C., the effect of stabilizing the contact resistance was markedly achieved compared with that in Embodiments 1 and 2 in which the substrate temperature was lower than that in Embodiment 3. These results showed that the contact resistance could be further stabilized by increasing the temperature during the annealing.

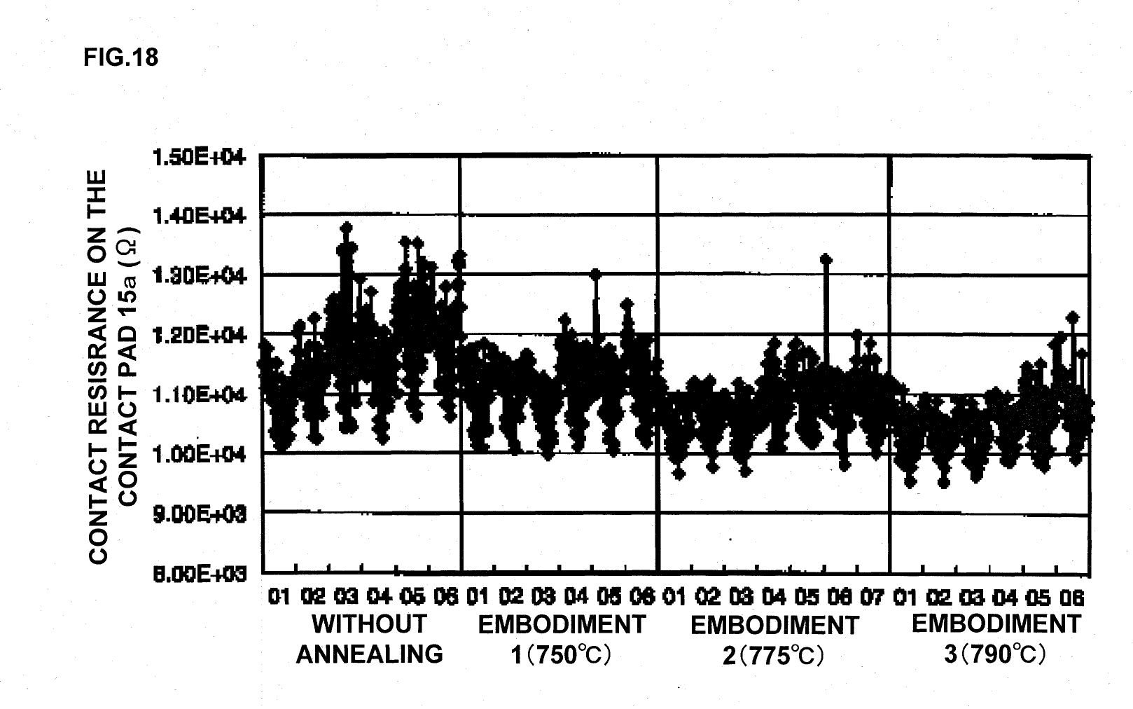

FIG. 18 is a graph showing results of an examination of the contact resistance between a contact pad 15a of a gate electrode 15 and a first conductive plug 24 thereon. The examination was performed as in the experiments whose results are shown in FIG. 17.

As shown in FIG. 18, on the contact pad 15a, the contact resistance of the first conductive plug 24 was also stabilized by performing the annealing of the nitride of the refractory metal film 22b. The results also showed that the contact resistance could be further stabilized by increasing the temperature during the annealing.

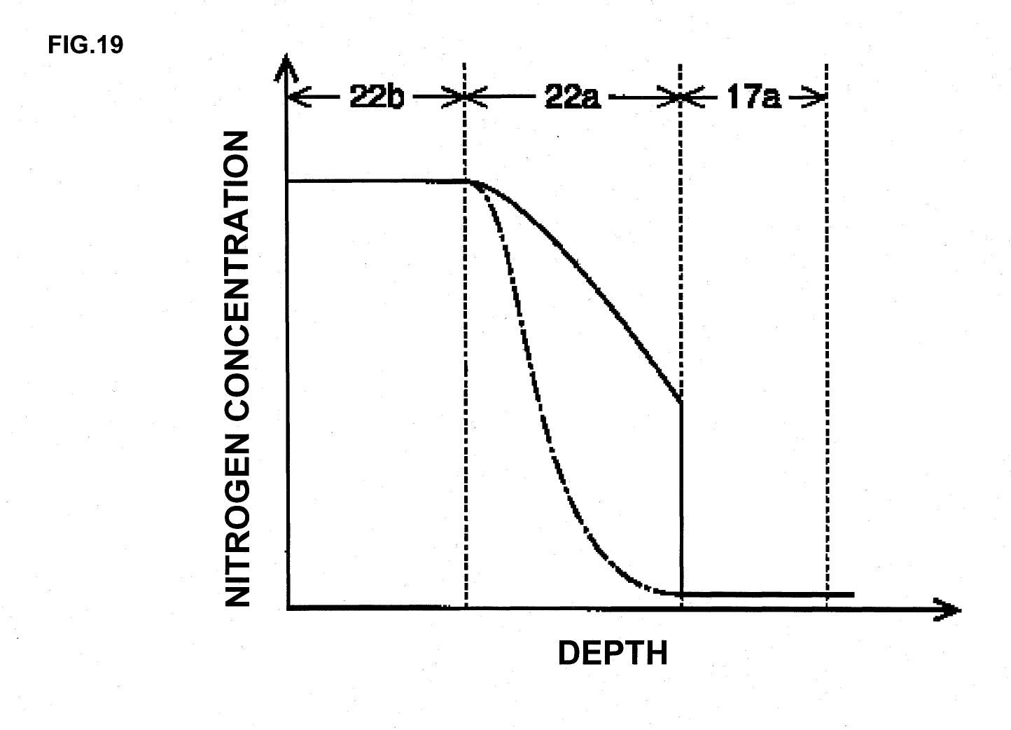

FIG. 19 is a graph that schematically shows profiles of the nitrogen concentration in films in the cases where annealing of the nitride of the refractory metal film 22b was performed (solid line) and the annealing was not performed (chain line). The horizontal axis of the graph of FIG. 19 represents the depth from the top surface of the diffusion-preventing film 22b.

As shown in the graph of FIG. 19, when annealing of the nitride of the refractory metal film 22b was not performed (chain line), only the surface layer of the barrier metal film 22a was substantially nitrided. As a result, the nitrogen concentration in the barrier metal film 22a was continuously decreased from the top surface to the bottom surface of the barrier metal film 22a. The nitrogen concentration on the bottom surface of the barrier metal film 22a was substantially zero as in the nitrogen concentration on the top surface of the metal silicide film 17a.

In contrast, in the above embodiment (solid line) in which annealing of the nitride of the refractory metal film 22b was performed, nitrogen was diffused in the barrier metal film 22a by the annealing. The effect of diffusion decreased as the distance from the top surface of the first barrier metal 22a increased. Therefore, the nitrogen concentration in the barrier metal film 22a was monotonically decreased from the top surface to the bottom surface thereof. However, since the effect of the annealing extended to the bottom surface of the barrier metal film 22a, the nitrogen concentration on the bottom surface of the barrier metal film 22a was higher than the nitrogen concentration on the top surface of the metal silicide film 17a.

As described above, the semiconductor device obtained by annealing the nitride of the refractory metal film 22b is characterized in that the nitrogen concentration in the barrier metal film 22a is monotonically decreased from the top surface to the bottom surface of the barrier metal film 22a. In addition, the semiconductor device is characterized in that the nitrogen concentration on the bottom surface of the barrier metal film 22a is higher than the nitrogen concentration on the top surface of the metal silicide film 17a.

According to examinations made by the present inventor, destabilization of the contact resistances of the first conductive plugs 24 tends to occur in a process of producing a semiconductor device including a ferroelectric capacitor Q, for example an FeRAM, rather than a process of producing a normal logic device.

In the formation of the ferroelectric capacitor Q, as described above, crystallization annealing of the ferroelectric film 32 and recovery annealing of the capacitor dielectric film 32a are performed. These annealing steps are performed at high substrate temperatures. For example, the crystallization annealing is performed at about 725° C. and the recovery annealing is performed at about 650° C.

A process of producing a logic device not including a ferroelectric capacitor Q does not include a step performed at such a high substrate temperature after the formation of MOS transistors. Therefore, it is believed that destabilization of the contact resistances of the first conductive plugs 24 is accelerated by the crystallization annealing and the recovery annealing, which are particularly performed for FeRAMs. Accordingly, when annealing of the nitride of the refractory metal film 22b in this embodiment is performed in the process of producing a FeRAM, the effect of stabilizing the contact resistance can be markedly achieved.

What is claimed is:

1. A semiconductor device comprising:
a conductive film formed over a substrate;
an insulating film formed over the conductive film, and having a hole on the conductive film; and
a conductive plug formed in the hole including a barrier metal film and a conductive film;
wherein a nitride concentration of the barrier metal film is decreased towards an interface between the barrier metal film and the conductive film, and the nitride concentration of the side of the barrier metal film is higher than the nitride concentration of the side of the conductive film at the interface.

2. The semiconductor device according to claim 1, wherein the barrier metal film includes a metal film and a metal nitride film.

3. The semiconductor device according to claim 1, wherein the metal film includes titanium or tantalum, and the nitride metal film includes titanium nitride or tantalum nitride.

4. The semiconductor device according to claim 1, further comprising a capacitor including an upper electrode, a capacitor dielectric film formed by ferroelectric material and a lower electrode are formed on the insulating film.

5. A method of manufacturing a semiconductor device, comprising:
forming a conductive film over a substrate;
forming a first insulating film over the conductive film;
forming a first hole on the conductive film in the first insulating film;
forming a barrier metal film in the first hole over a surface of the conductive film, wherein nitride concentration of the barrier metal film decreases towards the interface between the barrier metal film and the conductive film;
performing a first annealing the barrier metal film;
after the first annealing, forming a conductive film over the barrier metal film.

6. The method according to claim 5, wherein forming the barrier metal film includes forming a metal film over the conductive film, and forming a metal nitride film over the metal film.

7. The method according to claim 5, wherein the first annealing is performed in a nitrogen atmosphere without oxygen.

8. The method according to claim 5, wherein the first annealing is performed in the atmospheric pressure.

9. The method according to claim 5, before forming the metal nitride film, a second annealing of the metal film is performed.

10. The method according to claim 9, wherein the maximum substrate temperature in the first annealing is higher than the maximum substrate temperature in the second annealing.

11. The method according to claim 9, wherein the conduct film includes a metal silicide, and the maximum substrate temperature in the first annealing or the maximum substrate temperature in the second annealing is lower than the substrate maximum temperature in the forming of the conductive metal.

12. The method according to claim 11, wherein the metal silicide includes titanium silicide film or cobalt film, when including the titanium silicide, the maximum substrate temperature of the first annealing is equal or lower than 800 degrees Celsius, and when including the cobalt silicide, the maximum substrate temperature of the first annealing is equal or lower than 840 degrees Celsius.

13. The method according to claim 11, further comprising: forming the impurity diffusion region on the surface layer of the substrate, forming the metal silicide film on the impurity diffusion region.

14. The method according to claim 13, wherein the impurity diffusion region is a source/drain region or a well tap region of a MOS transistor.

15. The method according to claim 11, further comprising: forming the semiconductor patterns including silicon on the substrate, and forming the silicide film on the surface layer of the semiconductor pattern.

16. The method according to claim 5, wherein the metal nitride film is formed by the CVD (Chemical Vapor Deposition) method.

17. The method according to claim 5, further comprising: forming an upper electrode, a capacitor dielectric film by ferroelectric material, and a lower electrode over the insulating film.

18. The method according to claim 17, further comprising: forming the capacitor; forming a first conductive film over the first insulating film; forming a ferroelectric film over the first conductive film; forming a second conductive film over the ferroelectric film; patterning the first conductive film, the ferroelectric layer, and the second conductive film.

19. The method according to claim 17, further comprising: annealing the capacitor dielectric film in the oxygen atmosphere.

20. The method according to claim 17, further comprising: remaining the conductive film for a plug, the metal nitride film and the metal film as a first conductive plug in the first hole; forming a second insulating film over the capacitor and the first insulating film; forming a second hole in the second insulating film over the first conductive plug; forming a second conductive plug electrically connected to the first conductive plug in the second hole.
